(19) United States
(12) Patent Application Publication
(10) Pub. No.: US 2006/0151199 A1
(43) Pub. Date: Jul. 13, 2006

(54) Wire binder

(75) Inventors: Tatsuya Uchizono, Echizen-shi (JP); Toshifumi Sasaoka, Echizen-shi (JP); Yoshikazu Yonezu, Echizen-shi (JP); Toru Motonaga, Echizen-shi (JP)

Correspondence Address: REED SMITH LLP, Suite 1400, 3110 Fairview Park Drive, Falls Church, VA, 22042, US

(73) Assignee: Orion Electric Company Ltd.

(21) Appl. No.: 11/289,379

(22) Filed: Nov. 30, 2005

(30) Foreign Application Priority Data
Dec. 27, 2004 (JP) 2004-376779

(51) Int. Cl. H05K 7/14; F16B 33/00

(52) U.S. Cl. 174/138 D; 174/138 R

(57) ABSTRACT

According to the present invention, a wire binder 10 integrally includes a binding section 12 that binds a wire and a fixing section 20 that fixes the wire binder 10 to the plate 30, and is configured so that the wire binder 10 is engaged with the plate 30 by inserting legs 21a, 21b each having a hook 22a, 22b formed on its tip end and a protrusion 23 extending downward into attachment holes 31a, 31b, 31c formed in the plate 30, respectively, and so that protruding portions 23a, 23c consisting of inclined surfaces formed on the protrusion 23 are stopped at engagement sides 310a, 310c on which the protruding portions 23a, 23c are engaged with the attachment holes 31a, 31c formed in the plate 30, respectively.

### BACKGROUND OF THE INVENTION

1. Field of the Invention

The present invention relates to a wire binder attached to an attachment target member for binding a wire. More specifically, the present invention relates to an attachment structure of a wire binder considering instances in which the wire binder is attached to attachment target members having different thicknesses.

2. Description of the Related Art

Generally, if a wire is bound and attached to an attachment target member such as a plate, means for attaching a wire binder to the attachment target member and for fixing the wire is used. A structure of the means has been conventionally contrived variously. If the wire binder is employed for an electronic apparatus or the like which is required to store a substrate particularly on which an electronic component having a high voltage is mounted and a wire in a housing compactly, then a gap is formed between the attachment target member and the wire binder, and the gap causes various disadvantages as follows. The attachment target member and the wire binder engaged with each other are disengaged by vibration generated during transportation. If the wire binder is slightly inclined by as much as the gap, the bound wire contacts with the electronic component having the high voltage, resulting in an unexpected situation such as firing or breaking of the apparatus. Further, if the wire binder is slightly moved within the gap, contact noise is generated between the wire binder and the attachment target member, resulting in degradation of a product quality.

As for electronic apparatuses using many different types of substrates according to various products, if different wire binders are prepared for the substrates having different thicknesses, it disadvantageously takes much time and labor for maintenance of members. This is by no means a disadvantage that can be overlooked from viewpoints of manufacturing cost.

To overcome these disadvantages, Japanese Patent Application Laid-Open No. 2002-048110 discloses a structure of a wire binder as follows. The wire binder including stopper protrusions and elastically deformable pressure blades is inserted into a plate via through holes. The wire binder is rotated and attached to the plate so that the stopper protrusions are stopped on a rear surface of the plate through the through holes. The plate can be held between the pressure blades located on a front surface of the plate and the stopper protrusions located on the rear surface thereof. By employing the wire binder having the pressure blades that are elastically deformed as disclosed in Japanese Patent Application Laid-Open No. 2002-048110, even if the wire binder is to be attached to plates having different thicknesses, it is unnecessary to prepare a plurality of types of wire binders to correspond to the different thicknesses of the plates. Using the wire binder in one form, it is possible to deal with a change in thickness of the plate within a certain range.

Further, Japanese Patent Application Laid-Open No. 2002-276633 discloses a structure of a wire binder as follows. The wire binder that includes a flange consisting of an elastic member and elastic legs each of which is provided with a plurality of stepped stoppers and each of which is folded back into a V shape from a tip end of a support toward the top, is inserted into the plate through a through hole. The plate can be held between the elastic flange located on a front surface of the plate and the elastic legs located on a rear surface thereof. Japanese Patent Application Laid-Open No. 2002-276633 also discloses a method for fixedly attaching the wire binder to the plate as follows. A plurality of engagement holes are formed in the plate at predetermined positions, and a plurality of protrusions corresponding to the respective engagement holes are provided on an edge of the pressure blade. During attachment, the protrusions are fitted into the respective engagement holes, thereby fixedly attaching the wire binder to the plate. By employing the wire binder including the stepped stoppers provided on each elastic leg located on the rear surface of the plate, if the wire binder is to be attached to plates having different thicknesses, it is unnecessary to prepare a plurality of types of wire binders to correspond to the different thicknesses of the plates. Using the wire binder in one form, it is possible to deal with a change in thickness of the plate within a certain range.

These conventional techniques enable the wire binder in one form to deal with plates having different thicknesses. However, each of these conventional techniques has the following disadvantages. Since the portions between which the plate is held consist of the elastic members, a state of attaching the wire binder to the plate may possibly slightly differ according to a fluctuation in elasticity of the elastic members. Because of its complicated shape, the conventional wire binder requires slightly complicated operations in attachment steps such as a rotation operation performed when the wire binder is attached to the plate and a fitting operation of fitting the protrusions of the wire binder into the respective engagement holes of the plate. Besides, a cost of a mold for manufacturing the wire binder is increased.

### SUMMARY OF THE INVENTION

The present invention has been achieved to solve the conventional disadvantages. It is an object of the present invention to provide a wire binder which is highly versatile so as to be available for attachment target members having different thicknesses, which is simple in steps of attaching the wire binder to the attachment target member, which does not need to use an elastic member as a material for attachment portions, and which can make a cost of a mold for manufacturing the wire binder low because of its non-complicated shape.

In order to achieve the above-described object, the present invention provides a wire binder including: a binding section that binds a wire; and a fixing section that fixes the wire binder to an attachment target member, wherein the fixing section includes: engagement means for engaging the wire binder with the attachment target member; and gap restriction means for restricting a gap between the wire binder and the attachment target member. The present invention further provides, according to the above-described wire binder, the wire binder wherein the engagement means for attaching the wire binder to the attachment target member is provided by integrally forming a leg, which has a hook formed on a tip end, on the fixing section of the wire binder, by forming a through hole, with which the hook of the fixing section is engaged, in the attachment target member, and by engaging the hook with the through hole. The present invention further provides, according to the above-described wire binder, the wire binder wherein the gap restriction means for restricting the gap between the wire binder and the attachment target member is provided by forming a protruding portion, which has an inclined surface and which extends downward, on the fixing section of the wire binder, by forming a through hole, through which the protruding portion is inserted, in the attachment target member, and by abutting the inclined surface of the protruding portion on an edge of the through hole. Further, the present invention provides the wire binder wherein the gap restriction means for restricting the gap between the wire binder and the attachment target member is provided by forming a protruding portion, which has a generally stepped surface and which extends downward, on the fixing section of the wire binder, by forming a through hole, through which the protruding portion is inserted, in the attachment target member, and by causing the stepped surface of the protruding portion to be stopped on an edge of the through hole, instead of forming the protruding portion, which has an inclined surface and which extends downward, on the fixing section of the wire binder.

The present invention further provides, according to the above-described wire binder, the wire binder wherein a portion in which the leg is formed integrally with the protruding portion and a portion in which the leg and the protruding portion are formed separately are formed integrally on the same wire binder, and the through hole is formed in the attachment target member at a position corresponding to each of the portions of the wire binder. The present invention further provides, according to the above-described wire binder, the wire binder wherein a position at which the through hole for causing the protruding portion to be engaged with or stopped at the attachment target member is formed, is adjusted according to a thickness of the attachment target member.

According to the present invention, by providing the wire binder which is simple in steps of attaching the wire binder to the attachment target member, which does not need to use an elastic member as a material for attachment portions, and which is simple in form, a wire binder which can make a cost of a mold for manufacturing the wire binder low and which is highly versatile so as to be available for attachment target members having different thicknesses can be provided.

### BRIEF DESCRIPTION OF THE DRAWINGS

FIGS. 1A and 1B are perspective views of a wire binder according to a first embodiment of the present invention;

FIG. 2 is a front view of the wire binder according to the first embodiment;

FIGS. 3A to 3D are cross-sectional front views of the wire binder according to the first embodiment;

FIG. 4 is a cross-sectional front view of a wire binder according to a second embodiment of the present invention;

FIG. 5 is a cross-sectional front view of a wire binder according to a third embodiment of the present invention; and

FIG. 6 is a cross-sectional front view of a wire binder according to a fourth embodiment of the present invention.

### DESCRIPTION OF THE PREFERRED EMBODIMENTS

Implemental embodiments of the present invention will be described hereinafter with reference to the drawings.

### First Embodiment

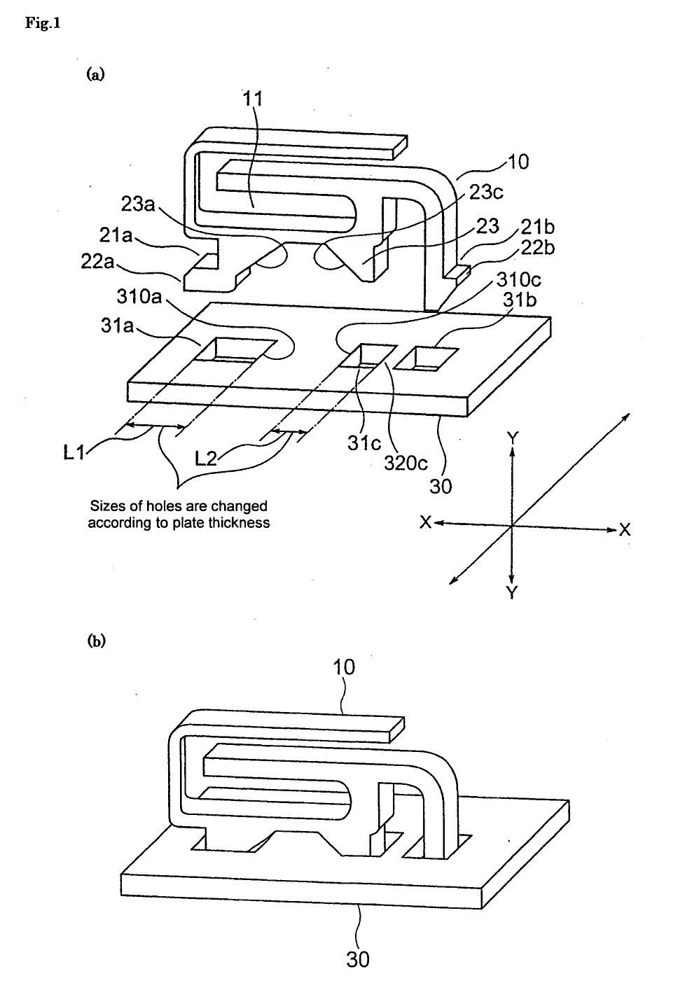

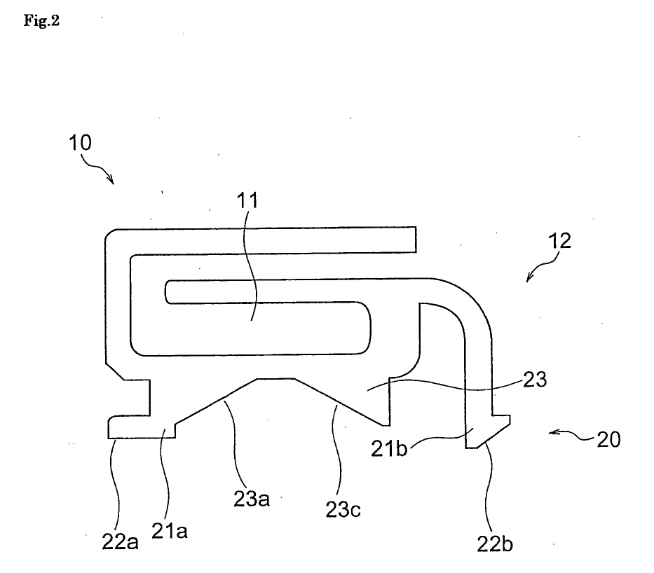

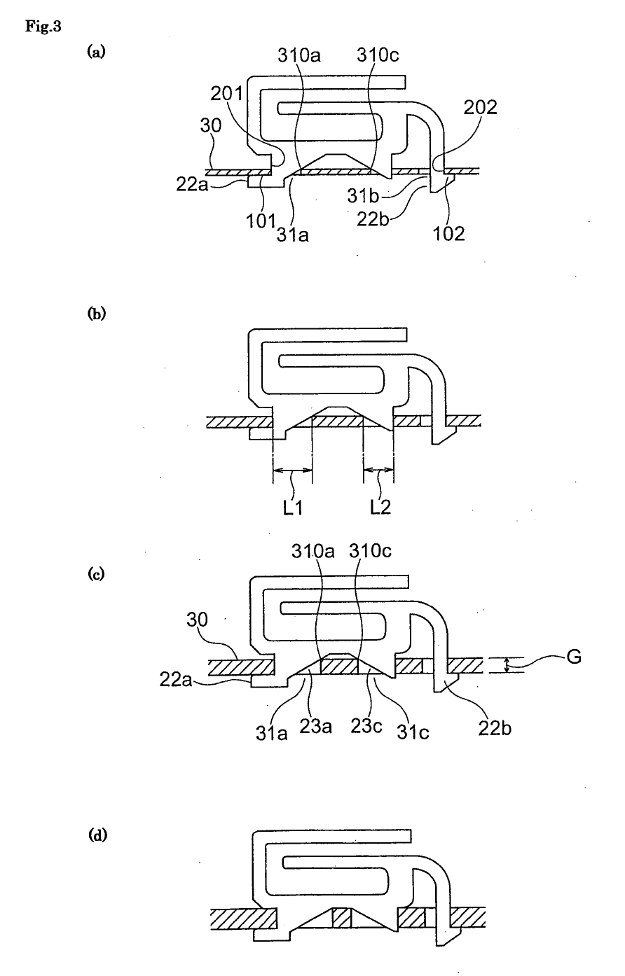

FIGS. 1A and 1B, 2, and 3A to 3D show a first embodiment of the present invention. FIGS. 1A and 1B are perspective views of a wire binder 10, wherein FIG. 1A is a perspective view of the wire binder 10 before the wire binder 10 is attached to a plate 30 and FIG. 1B is a perspective view of the wire binder 10 after the wire binder 10 is attached to the plate 30. FIG. 2 is a front view of the wire binder 10. FIGS. 3A to 3D are cross-sectional front views that depict states of the wire binder 10 attached to plates having different thicknesses, respectively according to the first embodiment.

A configuration and an operation of the wire binder 10 according to this embodiment will be described with reference to FIGS. 1A, 1B, and 2. The wire binder 10 according to this embodiment consists of a binding section 12 that functions to bind and store a wire, and a fixing section 20 that engages the wire binder 10 with the plate 30 to attach the wire binder 10 to the plate 30. If the wire binder 10 is attached to the plate 30, then the binding section 12 is located on one surface of the plate 30 and the fixing section 20 is located on the other surface of the plate 30.

The fixing section 20 includes a pair of legs 21a and 21b extending from the binding section 12, and hooks 22a and 22b that fix the wire binder 10 to the plate 30 are provided on tip ends of a first leg 21a and a second leg 21b that constitute the paired legs, respectively.

A first protruding portion 23a inclined relative to the surface of the plate 30 is formed on the first leg 21a that constitutes the paired legs. A protrusion 23 including a second protruding portion 23c inclined relative to the surface of the plate 30 similarly to the first protruding portion 23a is formed between the paired legs 21a and 21b. As shown in FIG. 1A, an inclined surface of the first protruding portion 23a and that of the second protruding portion 23c are formed so that they face each other, and so that a distance between them is gradually wider in a direction in which the wire binder 10 is inserted into the plate 30.

As shown in FIG. 1A, the plate 30 has attachment holes 31a, 31b, and 31c formed therein for attaching the wire binder 10 to the plate 30. The first leg 21a, the second leg 21b, and the protrusion 23 are inserted into the plate 30 to correspond to the attachment holes 31a, 31b, and 31c, respectively. If the insertion proceeds, the inclined surface of the first protruding portion 23a and that of the second protruding portion 23c are engaged with sides 310a and 310c of the attachment holes 31a and 31c in a Y-axis direction, respectively.

FIGS. 3A to 3D are cross-sectional front views that show instances in which the wire binder 10 is attached to plates 30 having different thicknesses, respectively. As typically shown in FIG. 3C, the inclined surface of the first protruding portion 23a and that of the second protruding portion 23c are engaged with the sides 310a and 310c of the attachment holes 31a and 31c, respectively. In addition, lengths L1 and L2 of the sides of the attachment holes 31a and 31c in an X-axis direction are adjusted to correspond to each of the different thicknesses of the plates 30 so that a length of a perpendicular G drawn from their engagement positions to the surface on which the hooks 22a and 22b provided on the paired legs 21a and 21b are engaged with the plate 30 is equal to the thickness of the plate 30. As evident from FIGS. 3A to 3D, if the wire binder 10 is attached to the plates 30 having different thicknesses, the lengths L1 and L2 of the sides of the attachment holes 31a and 31c in the X-axis direction differ among FIGS. 3A to 3D according to the thicknesses. Namely, it is necessary to determine magnitudes of the attachment holes to be formed according to the thickness of the plate to be used in advance, and to form the attachment holes having predetermined magnitudes at the time of designing the plate.

On completion of the insertion, the hooks 22a and 22b provided on the tip ends of the first leg 21a and the second leg 21b, respectively, are engaged with the rear surface of the plate 30. It is, therefore, possible to attach the wire binder 10 to the plate 30 without a gap.

As shown in FIG. 3A, a movement of the wire binder 10 in the Y-axis direction is suppressed by engagement surfaces 101 and 102 on which the hook 22a of the first leg 21a and the hook 22b of the second leg 21b are engaged with the plate 30, respectively, and by the engagement sides 310a and 310c on which the inclined surfaces of the protruding portions 23a and 23c are engaged with the attachment holes 31a and 31c, respectively. In addition, a movement of the wire binder 10 in the X-axis direction is suppressed by engagement of the hook 22a of the first leg 21a and the hook 22b of the second leg 21b with the attachment holes 31a and 31b formed in the plate 30, respectively.

### Second Embodiment

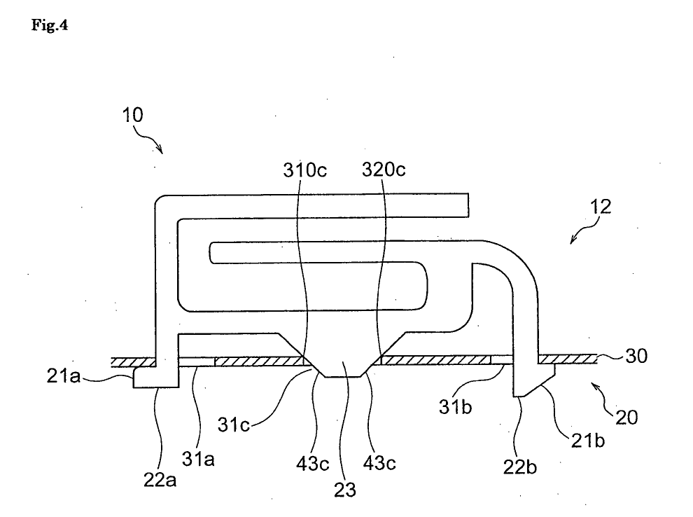

FIG. 4 is a cross-sectional front view that depicts a state of a wire binder 10 according to a second embodiment of the present invention.

The second embodiment is completely the same as the first embodiment in that the wire binder 10 includes the binding section 12 and the paired legs 21a and 21b having hooks 22a and 22b formed on their respective tip ends for fixing the plate 30. The second embodiment, however, differs from the first embodiment in the following respects. Two protruding portions 43c inclined relative to the surface of the plate 30 are formed on two surfaces of the protrusion 23 facing in opposite directions, respectively. In addition, the protrusion 23 is formed so that a distance between the inclined surfaces of the two protruding portions 43c is gradually narrower in a direction in which the wire binder 10 is inserted into the plate 30.

As shown in FIG. 4, the plate 30 has the attachment holes 31a, 31b, and 31c formed therein for attaching the wire binder 10 to the plate 30. The first leg 21a, the second leg 21b, and the protrusion 23 are inserted into the plate 30 to correspond to the attachment holes 31a, 31b, and 31c, respectively. If the insertion proceeds, the protrusion 23 including the two protruding portions 43c is engaged with sides 310c and 320c of the attachment hole 31c in the Y-axis direction.

In this embodiment, the two inclined surfaces of the two protruding portions 43c are engaged with the sides 310c and 320c of the attachment hole 31c, respectively. In addition, the length L2 of the side of the attachment hole 31c in the X-axis direction is adjusted to correspond to each of the different thicknesses of the plates 30 so that the length of the perpendicular G drawn from each engagement position to the surface on which the hooks 22a and 22b provided on the paired legs 21a and 21b are engaged with the plate 30 is equal to the thickness of the plate 30. Namely, it is necessary to determine magnitudes of the attachment holes to be formed in the plate such as a substrate according to the thickness of the plate to be used in advance, and to form the attachment holes having predetermined magnitudes at the time of designing of the plate such as the substrate.

On completion of the insertion, the hooks 22a and 22b provided on the tip ends of the first leg 21a and the second leg 21b, respectively, are engaged with the rear surface of the plate 30. It is, therefore, possible to attach the wire binder 10 to the plate 30 without a gap.

The movements of the wire binder 10 in the Y-axis direction and the X-axis direction are suppressed exactly in the same manner as that according to the first embodiment, which will not be, therefore, repeatedly described herein.

### Third Embodiment

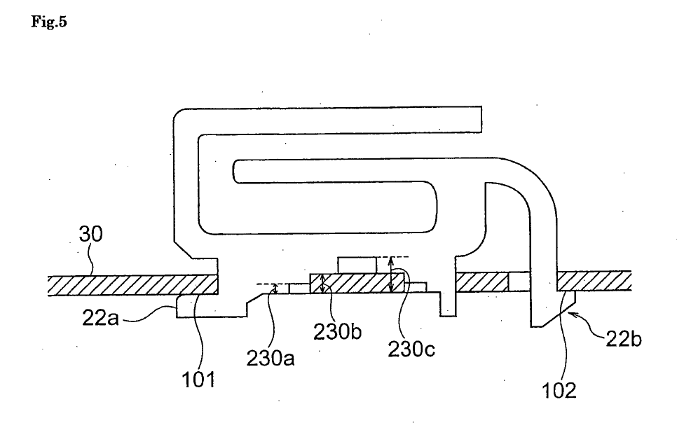

FIG. 5 is a cross-sectional front view that depicts a state of a wire binder 10 according to a third embodiment of the present invention.

The wire binder 10 according to the third embodiment is configured so that the inclined surface of the first protruding portion 23a and that of the second protruding portion 23c engaged with the surface of the plate 30 according to the first embodiment have a plurality of stepped parts, respectively. As shown in FIG. 5, according to the thickness of the plate 30 to be used, each of the inclined surfaces of the first protruding portion 23a and the second protruding portion 23c has stepped parts at heights of 230a, 230b, and 230c. In the first embodiment, the movement of the wire binder 10 in the Y-axis direction is suppressed by the engagement surfaces 101 and 102 on which the hook 22a of the first leg 21a and the hook 22b of the second leg 21b are engaged with the plate 30, respectively, and the engagement sides 310a and 310c on which the inclined surfaces of the protruding portions 23a and 23c are engaged with the attachment holes 31a and 31c, respectively. In the third embodiment, by contrast, the engagement surfaces 101 and 102 on which the hook 22a of the first leg 21a and the hook 22b of the second leg 21b are engaged with the plate 30, respectively, and the protruding portion-side stepped surfaces of the wire binder 10 are pressure-bonded to the surface of the plate 10. It is, therefore, advantageously possible to further suppress the movement of the wire binder 10 in the Y-axis direction.

### Fourth Embodiment

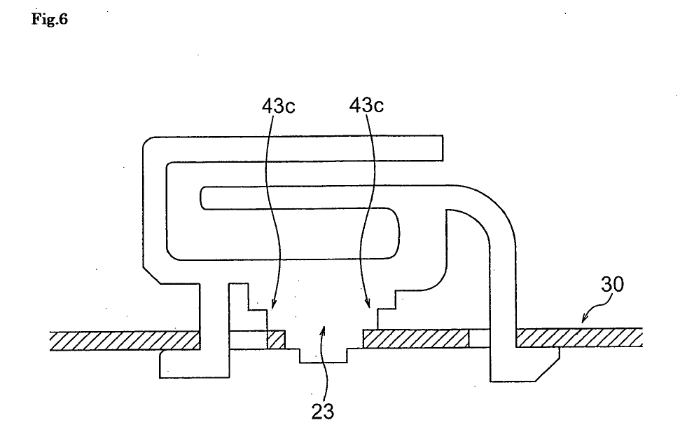

FIG. 6 is a cross-sectional front view that depicts a state of a wire binder 10 according to a fourth embodiment of the present invention.

The wire binder 10 according to the fourth embodiment is configured so that two inclined surfaces of the protrusion 23 having the two inclined protruding portions 43c facing in opposite directions and engaged with the surface of the plate 30 according to the second embodiment have a plurality of stepped parts, respectively. As shown in FIG. 6, according to the thickness of the plate 30 to be used, the inclined surfaces of the protrusion 23 have a plurality of stepped parts. As compared with the second embodiment, the movement of the wire binder 10 in the Y-axis direction can be advantageously further suppressed according to this embodiment, similarly to the third embodiment advantageous over the first embodiment.

In the drawings with reference to which the embodiments have been described, a wire storage portion that constitutes the binding section in one form is shown. However, the form of the wire storage portion is not limited to that according to the embodiments. The wire storage portion in whichever form can be available as long as it can be formed integrally with the fixing section of the wire binder according to the present invention.

1. A wire binder comprising:
a binding section that binds a wire; and
a fixing section that fixes the wire binder to an attachment target member, wherein
the fixing section includes:
engagement means for engaging the wire binder with the attachment target member; and
gap restriction means for restricting a gap between the wire binder and the attachment target member.

2. The wire binder according to claim 1, wherein
the engagement means for attaching the wire binder to the attachment target member is provided by integrally forming a leg, which has a hook formed on a tip end, on the fixing section of the wire binder, by forming a through hole, with which the hook of the fixing section is engaged, in the attachment target member, and by engaging the hook with the through hole.

3. The wire binder according to claim 1, wherein
the gap restriction means for restricting the gap between the wire binder and the attachment target member is provided by forming a protruding portion, which has an inclined surface and which extends downward, on the fixing section of the wire binder, by forming a through hole, through which the protruding portion is inserted, in the attachment target member, and by abutting the inclined surface of the protruding portion on an edge of the through hole.

4. The wire binder according to claim 1, wherein
the gap restriction means for restricting the gap between the wire binder and the attachment target member is provided by forming a protruding portion, which has a generally stepped surface and which extends downward, on the fixing section of the wire binder, by forming a through hole, through which the protruding portion is inserted, in the attachment target member, and by causing the stepped surface of the protruding portion to be stopped on an edge of the through hole.

5. The wire binder according to claim 3, wherein
a portion in which the leg is formed integrally with the protruding portion and a portion in which the leg and the protruding portion are formed separately are formed integrally on the same wire binder, and
the through hole is formed in the attachment target member at a position corresponding to each of the portions of the wire binder.

6. The wire binder according to claim 3, wherein
a position at which the through hole for causing the protruding portion to be engaged with or stopped at the attachment target member is formed, is adjusted according to a thickness of the attachment target member.

7. An electronic apparatus comprising the wire binder according to claim 1, wherein
the wire binder is employed to bind and hold a wire arranged inside the electronic apparatus at an appropriate position.

8. The wire binder according to claim 2, wherein
the gap restriction means for restricting the gap between the wire binder and the attachment target member is provided by forming a protruding portion, which has an inclined surface and which extends downward, on the fixing section of the wire binder, by forming a through hole, through which the protruding portion is inserted, in the attachment target member, and by abutting the inclined surface of the protruding portion on an edge of the through hole.

9. The wire binder according to claim 2, wherein
the gap restriction means for restricting the gap between the wire binder and the attachment target member is provided by forming a protruding portion, which has a generally stepped surface and which extends downward, on the fixing section of the wire binder, by forming a through hole, through which the protruding portion is inserted, in the attachment target member, and by causing the stepped surface of the protruding portion to be stopped on an edge of the through hole.

10. The wire binder according to claim 8, wherein
a portion in which the leg is formed integrally with the protruding portion and a portion in which the leg and the protruding portion are formed separately are formed integrally on the same wire binder, and
the through hole is formed in the attachment target member at a position corresponding to each of the portions of the wire binder.

11. The wire binder according to claim 4, wherein
a portion in which the leg is formed integrally with the protruding portion and a portion in which the leg and the protruding portion are formed separately are formed integrally on the same wire binder, and
the through hole is formed in the attachment target member at a position corresponding to each of the portions of the wire binder.

12. The wire binder according to claim 9, wherein
a portion in which the leg is formed integrally with the protruding portion and a portion in which the leg and the protruding portion are formed separately are formed integrally on the same wire binder, and
the through hole is formed in the attachment target member at a position corresponding to each of the portions of the wire binder.

13. The wire binder according to claim 8, wherein
a position at which the through hole for causing the protruding portion to be engaged with or stopped at the attachment target member is formed, is adjusted according to a thickness of the attachment target member.

14. The wire binder according claim 4, wherein
a position at which the through hole for causing the protruding portion to be engaged with or stopped at the attachment target member is formed, is adjusted according to a thickness of the attachment target member.

15. The wire binder according to claim 9, wherein
a position at which the through hole for causing the protruding portion to be engaged with or stopped at the attachment target member is formed, is adjusted according to a thickness of the attachment target member.

16. The wire binder according to claim 5, wherein
a position at which the through hole for causing the protruding portion to be engaged with or stopped at the attachment target member is formed, is adjusted according to a thickness of the attachment target member.

17. The wire binder according to claim 10, wherein
a position at which the through hole for causing the protruding portion to be engaged with or stopped at the attachment target member is formed, is adjusted according to a thickness of the attachment target member.

18. The wire binder according to claim 11, wherein
a position at which the through hole for causing the protruding portion to be engaged with or stopped at the attachment target member is formed, is adjusted according to a thickness of the attachment target member.

19. The wire binder according to claim 12, wherein
a position at which the through hole for causing the protruding portion to be engaged with or stopped at the attachment target member is formed, is adjusted according to a thickness of the attachment target member.
